(19) United States
(12) Patent Application Publication
(10) Pub. No.: US 2013/0093015 A1
(43) Pub. Date: Apr. 18, 2013

(54) HIGH VOLTAGE MOS TRANSISTOR

(71) Applicants: Deb Kumar Pal, Kuching (MY); Elizabeth Ching Tee Kho, Kuching (MY); Alexander Dietrich Hölke, Kuching (MY)

(72) Inventors: Deb Kumar Pal, Kuching (MY); Elizabeth Ching Tee Kho, Kuching (MY); Alexander Dietrich Hölke, Kuching (MY)

(73) Assignee: X-FAB SEMICONDUCTOR FOUNDRIES AG, Erfurt (DE)

(21) Appl. No.: 13/581,769

(22) PCT Filed: Mar. 1, 2010
(86) PCT No.: PCT/EP10/52568

§ 371 Date: Dec. 19, 2012

(51) Int. Cl. H01L 29/78; H01L 29/66

(52) U.S. Cl. CPC H01L 29/7816; H01L 29/66681
USPC 257/339; 438/285

(57) ABSTRACT

A high voltage metal oxide semiconductor (HVMOS) transistor (1) comprises a drift region (8) comprising a material having a mobility which is higher than a mobility of Si. There is also provided a method of manufacturing said transistor, the method comprising forming a drift region comprising a material having a mobility which is higher than a mobility of Silicon. The material can be a Si—Ge strained material. The on- resistance is reduced compared to a transistor with a drift region made of Si, so that the trade-off between breakdown voltage and on-resistance is improved.

The present invention relates to high voltage transistors, and particularly High Voltage Metal Oxide Semiconductor (HVMOS) transistors. The invention finds particular application in High Voltage Laterally Diffused Metal Oxide Semiconductor (HVLDMOS) transistors for use in power electronics applications.

Desirable features of HVMOS transistors for power electronics applications are low specific on-resistance (Rdson), high drive current, low gate to drain capacitance, high transconductance and high breakdown voltage (BV) [see e.g. C. Hu, M. H. Chi and V. M. Patel “Optimum design of Power MOSFETs,” IEEE Trans on Electron Devices, Vol 31, no 12, P 1693-1700, 1984; B. J. Baliga, “An overview of smart power technology”, IEEE Trans on Electron Devices, Vol 38, no 7, P 1568-1575, 1991; R. P. Zingg, “On the specific on resistance of high voltage and power devices,” IEEE Trans on Electron Devices, Vol 51, no 3, P 492-499, 2004]. Designing HVMOS transistors for a specific application is normally a trade-off between these parameters because these parameters are linked to each other from a transistor technology point of view. Improving one parameter normally adversely affects at least one other parameter.

The most desired measure of performance for all applications is usually low Rdson and high BV. Typically, an attempt to improve the BV of a HVMOS transistor drastically increases the Rdson [see e.g. R. P. Zingg, “On the specific on resistance of high voltage and power devices,” IEEE Trans on Electron Devices, Vol 51, no 3, P 492-499, 2004], i.e. the BV requirement always limits the reduction of Rdson. The Reduced Surface Field (RESURF) [see e.g. J. Appels, M. Collet, P. Hart, H. Vaes and J. Verhoeven, “Thin layer HV devices” Philips J. Research, Vol 35, no 1, P 1-13, 1980; S. Colak, B. Singer and E. Stupp, “LDMOS Power transistor design,” IEEE Electron Device Letter, Vol 1, P 51-53, 1980; Z. Parpia, A. Salama, “Optimization of RESURF LDMOS”, IEEE Trans on Electron Devices, Vol 37, P 789-796, 1990] is a commonly used technique to address the trade-off between the BV and Rdson. Applying the RESURF technique to the LDMOS transistors avoids the avalanche breakdown at the device surface.

A typical RESURF HVLDMOS transistor cross section is shown in FIG. 1 of the accompanying drawings. Transistor 1 is fabricated in a substrate 2. A well 3 is formed within the substrate 2 towards one side of the transistor. A source 4 is formed as a highly doped area inside well 3, the source being laterally connected to a channel through a Lightly Doped Drain (LDD) 5. A heavily doped area 6 is formed as a well pick-up 6. There is an oxide 7 between the source 4 and the well pick-up 6 for isolation purposes. An extended doped region 8, which functions as a drift region 8, is formed inside the substrate 2 towards the other side of the transistor, and a drain 9 is formed within the drift region 8. The well 3 is therefore separated from the drain 9 by the drift region 8. The drift region 8 is normally lightly doped whereas the drain 9 is typically heavily doped. The doping polarity of the drift region 8 and drain 9 is opposite to the doping polarity of the substrate 2 and well 3. A gate 10, made of polysilicon, is deposited on the surface between the drain 9 and source 4. A gate oxide layer 11 is located under the gate. L-shaped spacers 12 are formed on the left and right sides of the gate 10.

In the off-state of the transistor 1 shown in FIG. 1, the drift region 8 supports high reverse bias voltage applied at the drain 9. The RESURF technique employs the interaction between the depletion of two pn junction diodes to reduce the electrical field at the surface. The first pn junction is a vertical junction formed between the well 3 and drift region 8, the second pn junction is a horizontal junction formed by the substrate 2 and drift region 8. The surface breakdown of the transistor 1 is substantially eliminated by enhancing depletion layer thickness of the horizontal and vertical junctions, so the drift region is fully depleted before a surface electric field reaches its critical breakdown value. The device breakdown occurs in a bulk location at the parallel plane junction (or horizontal junction) formed between the substrate 2 and drift region 8. An ideal depletion is accomplished by controlling the amount of charge carriers in the drift region 8. The drift region charge carriers are calculated from a product of the drift region doping concentration and the thickness of the drift region. The maximum BV is achieved when the drift region charge carriers are present in the order of 2×10¹² cm⁻². This condition is known as the RESURF condition, which defines a limit on the upper bound of the doping concentration in the drift region and therefore on the minimum achievable Rdson.

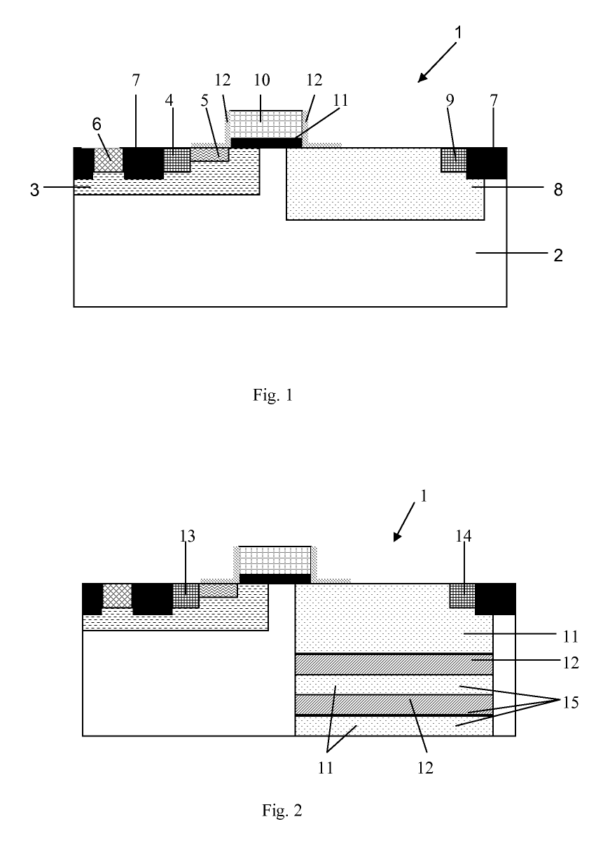

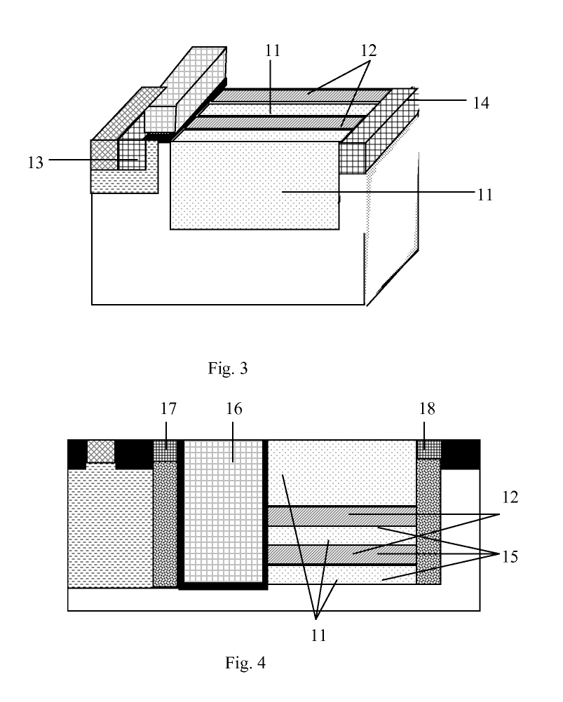

Another technique namely Superjunction (SJ) [see e.g. X. B. Chen, P.A. Mawby, K. Board and C. A. T. Salama, “Theory of a Novel voltage sustaining layer for power devices,” Microelectronics Journal, Vol 29, P 1005-1011, 1998] applied to LDMOS transistors aims to decrease the resistivity of the drift region without affecting the BV. FIG. 2 shows a horizontal superjunction (SJLDMOS) transistor and FIG. 3 shows a vertical SJLDMOS transistor. In these figures, many features are the same as in FIG. 1, but the drift region is different from that of FIG. 1. In FIGS. 2 and 3, the lightly doped drift region is replaced by alternating higher doped n regions (layers) 11 and p regions (layers) 12. These alternatingly doped layers 11, 12 form a multiple RESURF effect. These layers are narrow and the net dopings in both layers are approximately equal in order to maintain the RESURF condition: N_{D}W_{N}=N_{A}W_{P}˜2×10^{12 cm}⁻² where N_{D} and N_{A} are the net impurity doping concentration of the n layers 11 and p layers 12 where W_{N} and W_{P} are the respective widths of the layers.

In the off-state of the SJLDMOS transistors shown in FIGS. 2 and 3, an applied reverse bias results in a full depletion of the whole drift region 11, 12 due to the multiple RESURF effect. This results in a flat electric field distribution in the drift region 11, 12 which yields the highest possible BV for a given drift region length L_{D}. The flat electric field distribution is also independent of the drift region doping concentration. The BV is determined by L_{D}E_{C} where E_{C} is the critical electric field for a drift region material.

In the on-state of the SJLDMOS transistors shown in FIGS. 2 and 3, the Rdson is reduced due to the high doping concentration of current conducting drift layers 11. The current conducting drift layers 11 comprise a doping type which is the same as the doping type of source 13 and drain 14. The doping concentration of the current conducting drift layers 11 cannot be increased too much compared to a conventional structure because the conducting drift layers become too thin to fulfil the RESURF condition. In the on-state, the thin alternatingly doped layers 11, 12 are depleted due to a built-in potential between the alternatingly doped layers 11, 12. This depleted region increases the Rdson. The present inventors have appreciated that the high doping concentration of the drift region 11, 12 also reduces the mobility of the carriers, which results in an increased Rdson.

The alternatingly doped drift layers of high performance SJLDMOS transistors should have a high and tightly matched doping concentration. If the doping concentrations of the alternatingly doped drift layers are not equal, a charge imbalance occurs in the alternatingly doped drift layers, which results in a reduced BV. The charge imbalance is more pronounced at higher doping concentrations. A substrate assisted depletion can also result in a charge imbalance to further reduce the BV. The design of superjunction transistors should take account of this factor. The optimisation of the charge imbalance effect therefore results in a complicated and costly process.

Vertical SJLDMOS transistors (FIG. 3) are usually manufactured by using a multiple epitaxy or a trench/epitaxy technique in a precise manner to maintain a substantially ideal charge balance, but this increases the process cost. Horizontal SJLDMOS transistors (FIG. 2) can be manufactured by a multiple implants technique. However the doping concentration of the drift region can not be made very high because the width of the drift region cannot be controlled precisely with implantation. Furthermore, for the horizontal SJLDMOS transistors, the floating drift layers 15 (FIG. 2) adversely affect the switching applications.

In order to address the problems relating to floating drift layers 15 of FIG. 2 and also to address the trade-off between Rdson and BV, a Trench Gate Horizontal SJ transistor (FIG. 4) has been proposed [see S. Sridevan, D. M. Kinzer, “Bidirectional Shallow Trench Superjunction Device with RESURF Region,” U.S. Pat. No. 6,835,993 B2, Dec. 28, 2004]. Most features of FIG. 4 are the same as in FIG. 2, but the gate 16, source 17 and drain 18 are different from those of FIG. 2. A trench gate 16, a deep source 17 and a deep drain 18 are formed to connect the floating drift layers 15, which also reduces the Rdson by adding an extra conduction channel through the side walls of the trench gate. However the process for the Trench Gate SJ transistor is complicated and costly.

The inventors have appreciated that by using a high mobility material in the drift region, it is possible to address the trade-off between the Rdson and BV whilst retaining the benefit of a low cost and simple manufacturing CMOS process for HVLDMOS transistors.

According to one aspect of the present invention there is provided a high voltage metal oxide semiconductor (HVMOS) transistor comprising a drift region comprising a material having a mobility which is higher than a mobility of Silicon.

According to another aspect of the present invention there is provided a method of manufacturing a high voltage metal oxide semiconductor (HVMOS) transistor, the method comprising forming a drift region comprising a material having a mobility which is higher than a mobility of Silicon.

Further aspects of the invention are set out in the accompanying dependent claims.

Some preferred embodiments of the invention will now be described by way of example only and with reference to the accompanying drawings, in which:

FIG. 1 is a schematic cross-section of a known HVLDMOS transistor.

FIG. 2 is a schematic cross-section of a known horizontal superjunction HVLDMOS transistor.

FIG. 3 is a schematic cross-section of a known vertical superjunction HVLDMOS transistor.

FIG. 4 is a schematic cross-section of a known trench gate horizontal superjunction HVLDMOS transistor.

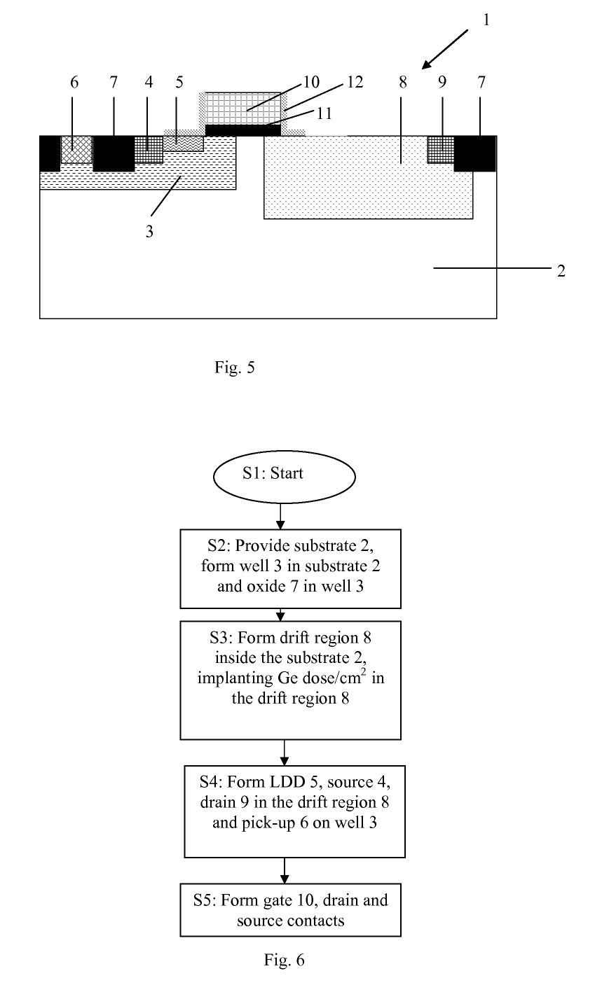

FIG. 5 is a schematic cross-section of a HVLDMOS transistor in accordance with an embodiment of the present invention.

FIG. 6 is a flow diagram illustrating the manufacturing steps for the HVLDMOS transistor of FIG. 5.

FIG. 5 illustrates a schematic cross section of a HVLDMOS transistor in accordance with an embodiment of the present invention. Many features are the same as in FIG. 1, carry the same reference and have the same or a similar function. Whilst in the prior art the drift region 8 comprises a Silicon material, the drift region 8 of FIG. 5 comprises a material having a mobility which is higher than a mobility of Silicon. The material is preferably a Silicon-Germanium (Si—Ge) strained material. It will be appreciated that the Si—Ge strained material can also be regarded as a Si—Ge strained layer. In the off-state the drift region, comprising the Si—Ge strained material, can be fully depleted to result in a BV which is the same or similar to the BV achieved by the HVLDMOS transistor of FIG. 1. In the on-state, the Rdson is reduced compared to that of an HVLDMOS transistor with a drift region comprising (substantially only) silicon material. This is because the Si—Ge strained material has a high mobility. The trade-off between the BV and Rdson can therefore be improved. It will be appreciated that the HVLDMOS transistor of FIG. 5 can be a n-channel LDMOS transistor (the doping polarity of drift region 8, source 4 and drain 9 is n-type) or a p-channel LDMOS transistor (the doping polarity of drift region 8, source 4 and drain 9 is p-type). For the n-channel transistor, an electron mobility of the Si—Ge strained material is between an electron mobility of Silicon and an electron mobility of Germanium. Likewise, for the p-channel LDMOS transistor, a hole mobility of the Si—Ge strained material is between a hole mobility of Silicon and a hole mobility of Germanium.

In preferred embodiments the Si—Ge strained material comprises between 5% and 35% of Ge.

Table 1 shows simulated results of Rdson and BV when the drift region 8 for the HVLDMOS transistor of FIG. 5 comprises different Ge doses. As seen from this table, the BV hardly changes but the Rdson decreases with the increase of the Ge dose/cm². As a result, the trade-off between the Rdson and BV is improved compared to a situation where no Ge dose/cm² is applied.

TABLE 1

| Device | Ge Dose/cm² | Rdson in mΩ*mm² | BV in volt |
|---|---|---|---|
| NMOSFET | NIL | 128.6 | 56.8 |
| | 1E16 | 124.2 | 56.7 |
| | 1E17 | 118.3 | 56.3 |
| PMOSFET | NIL | 456.1 | 39.1 |
| | 1E16 | 422.0 | 40.0 |
| | 1e17 | 338.8 | 40.3 |

It will be appreciated that the Si—Ge strained material can be formed from a standard band engineering for a heterojunction material. A detailed description of the band engineering can be found in heterostructure books [see e.g. John D. Cressler, Book “SiGe and Si Strained layer Epitaxy for Silicon Heterostructure Devices” 2007]. Ge is preferably used for straining Si because Ge is compatible for integrating in the standard Si CMOS process.

The inventors have appreciated that the Si—Ge stained material can be formed by an epitaxial growth technique in which the Si—Ge material is deposited by selective epitaxy on the drift region. However it has been found that forming the Si—Ge material by this technique is costly because it requires an extra mask for growing the epitaxy and also epitaxy itself is a costly process.

The inventors have further appreciated that an implantation technique for forming Si—Ge strained material can be adapted for use in connection with the present invention. The inventors prefer this technique since it is simple and cost effective. In this technique, the same mask or masking step which is used for implanting the drift region can also be used for implanting Ge.

The manufacturing steps for the HVLDMOS transistor of FIG. 5 are shown in FIG. 6, which are briefly described below and the reference numerals below correspond to those of FIG. 5:

S1: Starting the manufacturing process of the HVLDMOS of FIG. 5

S2: Providing the substrate 2 for forming different active regions on it, forming well 3 on the substrate 2 and forming oxide 7 in the well 3.

S3: Forming the drift region 8 inside the substrate 2, implanting Ge dose/cm² in the drift region 8 followed by drift implant with the same masking step.

S4: Forming the LDD 5, source 4, drain 9 in the drift region 8 and well pick-up 6 in the well 3.

S5: Forming the gate 10, source and drain contacts.

It will be appreciated that the Rdson of the SJ LDMOS transistors can be improved by using current conducting drift layers comprising Si—Ge strained material. In this arrangement, a current conducting drift layer such as the current conducting drift layer 11 (either only one current conducting drift layer 11 such as the current conducting drift layer at the surface of the device, or all current conducting drift layers) for the horizontal SJLDMOS shown in FIG. 2 comprises the Si—Ge material described in connection with FIG. 5. In the same way, the current conducting drift layer(s) 11 of the vertical SJLDMOS transistor shown in FIG. 3 may comprise the Si—Ge strained material. The current conducting drift layer(s) 11 comprising Si—Ge material can be formed by both the epitaxial technique and/or implantation with high energy.

The inventors have found that a III-V compound material such as InAs, GaAs or InGaAs etc may be used instead of Si—Ge as the material of the drift region. However, their integration in the standard Silicon CMOS process is more difficult.

It will be appreciated that the drift region for HVLDMOS transistors described above may comprise one or more drift layers. When the drift region comprises only one layer, preferably the material of the entire one layer is the Si—Ge strained material (or preferably the one drift layer is the Si—Ge strained layer). When the drift region comprises more than one drift layer (specifically for SJLDMOS transistors), it is possible that only the current conducting drift layer or layers of the plurality of drift layers comprise(s) the Si—Ge strained material (or the current conducting drift layer(s) may be the Si—Ge strained layer(s)).

The skilled person will understand that in the preceding description and appended claims, positional terms such as ‘under’, ‘lateral’, ‘vertical’, ‘horizontal’ etc. are made with reference to conceptual illustrations of a transistor, such as those showing standard cross-sectional perspectives and those shown in the appended drawings. These terms are used for ease of reference but are not intended to be of limiting nature. These terms are therefore to be understood as referring to a transistor when in an orientation as shown in the accompanying drawings.

It will be appreciated that all doping polarities mentioned above and those presumed by default could be reversed, the resulting devices still being in accordance with the present invention.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A high voltage metal oxide semiconductor (HVMOS) transistor comprising a drift region comprising a material having a mobility which is higher than a mobility of Silicon.

2. The HVMOS transistor of claim 1 wherein the mobility of said material comprises an electron mobility or a hole mobility.

3. The HVMOS transistor of claim 2 wherein the electron mobility of said material is between an electron mobility of Silicon (Si) and an electron mobility of Germanium (Ge).

4. The HVMOS transistor of claim 2 wherein the hole mobility of said material is between a hole mobility of Si and a hole mobility of Ge.

5. The HVMOS transistor of claim 1 wherein said material is a strained material.

6. The HVMOS transistor of claim 5, wherein the strained material is a Si—Ge strained material.

7. The HVMOS transistor of claim 6, wherein the Si—Ge strained material comprises more than 5% of Ge.

8. The HVMOS transistor of claim 6, wherein the Si—Ge strained material comprises less than 35% of Ge.

9. The HVMOS transistor of claim 6, wherein the mobility of the Si—Ge strained material is such that the specific on-resistance is reduced when compared with a transistor of similar construction but without the Si—Ge strained material.

10. The HVMOS transistor of claim 1, wherein the drift region comprises one or more current conducting drift layers, wherein the one or more drift layers comprises said material.

11. The HVMOS transistor of claim 1, wherein the transistor is a unipolar transistor.

12. The HVMOS transistor of claim 1, wherein the transistor is a High Voltage Laterally Diffused Metal Oxide (HVLDMOS) transistor.

13. The HVMOS transistor of claim 1, wherein the transistor is a high voltage Superjunction Laterally Diffused Metal Oxide (SJLDMOS) transistor.

14. The HVMOS transistor of claim 13, wherein the SJLDMOS transistor is a vertical SJLDMOS transistor or a horizontal SJLDMOS transistor.

15. The HVMOS transistor of claim 1, wherein said drift region comprises an epitaxial layer.

16. The HVMOS transistor of claim 1, wherein said drift region comprises an implanted layer.

17. A method of manufacturing a high voltage metal oxide semiconductor (HVMOS) transistor, the method comprising forming a drift region comprising a material having a mobility which is higher than a mobility of Silicon.

18. The method of claim 17, wherein the transistor is manufactured using standard CMOS and HBT processes.

19. The method of claim 17, wherein the drift region is formed using an epitaxial technique.

20. The method of claim 17, wherein the drift region is formed using an implantation technique.
